(19) United States
(12) Patent Application Publication
(10) Pub. No.: US 2008/0057725 A1
(43) Pub. Date: Mar. 6, 2008

(54) METHOD OF MANUFACTURING SEMICONDUCTOR DEVICE

(76) Inventor: Sang-Il Hwang, Gangwon-do (KR)

Correspondence Address: SHERR & NOURSE, PLLC, 620 HERNDON PARKWAY, SUITE 200, HERNDON, VA, 20170, US

(21) Appl. No.: 11/847,078

(22) Filed: Aug. 29, 2007

(30) Foreign Application Priority Data
Aug. 30, 2006 (KR) 10-2006-0082748

(51) Int. Cl. H01L 21/461; H01L 21/306

(52) U.S. Cl. 438/710; 156/345.1; 257/E21.483

(57) ABSTRACT

Disclosed herein a method of manufacturing a semiconductor device, the method including: forming a plurality of layers over a semiconductor substrate having a lower structure including a transistor; forming a photoresist layer over the plurality of layers and patterning the photoresist layer in a contact hole shape; and etching the plurality of layers through a predetermined etching method using the patterned photoresist layer as an etching mask to form a contact hole.

The present application claims priority under 35 U.S.C. 119 to Korean Patent Application No. 10-2006-0082748, filed on Aug. 30, 2006, which is hereby incorporated by reference in its entirety.

### BACKGROUND

In a multi-layer metal line forming process, an etching process forms a contact hole for connecting a metal line in a wiring layer to a lower structure including a transistor. An etching process for forming a contact hole in a 90-nm device is more troublesome than the etching process in a 130-nm device, using a hard mask in the related art. While a critical dimension of the contact hole in the 130-nm device may be about 160 nm, the critical dimension of the contact hole in the 90-nm device may be about 115 nm, which exceeds a resolution limit of a KrF light source. Accordingly, an ArF light source may be used. For the ArF light source, a different photoresist (PR) material is used. Since the light emitted from the ArF light source has a relatively short 193 nm wavelength, it is absorbed by the benzene ring structure of the PR used with the KrF light source. Thus, a different PR may be used, appropriate for ArF. The PR for ArF has a chemical structure with a relatively poor etch resistance. The thickness of the PR should be equal to or less than a predetermined value (about 3000 Å) to expose a pattern having a design rule for a 90 nm process. Since the etch resistance was relatively poor, but a relatively thin coat was specified by the design rule, a hard mask was used in a related etching process for forming a contact hole.

A related method of manufacturing a semiconductor device including a contact hole will be briefly described with reference to FIG. 1.

As shown in FIG. 1, a plurality of layers including a metal barrier layer 102, a pre-metal dielectric layer 103, an anti-reflection layer 104 and a hard mask layer 105 are formed over a semiconductor substrate 101 including a lower structure. The hard mask 105, the anti-reflection layer 104, the pre-metal dielectric layer 103 and the metal barrier layer 102 formed over the semiconductor substrate 101 are sequentially etched to form a contact hole.

However, to form the contact hole, the related etching process requires a complicated process using the hard mask, and cost efficiency deteriorates. In a structure having a relatively high aspect ratio, such as a 90-nm device, etching may stop prematurely due to a high temperature at the bottom of the substrate. Due to this premature etch stop, a metal line may not contact an active or gate region. Therefore, a signal output from the metal line is not transmitted to a desired location.

### SUMMARY

Embodiments relate to a method of manufacturing a semiconductor device capable of improving circularity of a contact hole in a process of forming a contact for electrically connecting metal lines. Embodiments relate to a method which prevents circularity of a contact hole from deteriorating due to low etch resistance of a PR for ArF by forming the contact hole of a first metal line using only a PR material without a hard mask.

Embodiments relate to a method for preventing an etch stop caused by a high temperature at the bottom of a substrate in a device having a large aspect ratio. Embodiments relate to a method of manufacturing a semiconductor device which may include forming a plurality of layers over a semiconductor substrate which may have a lower structure including a transistor. The plurality of layers may include a metal barrier layer, a pre-metal dielectric layer and an anti-reflection layer. A photoresist layer may be formed over the plurality of layers. The photoresist layer may be patterned for a contact hole. The plurality of layers are etched using a predetermined etching method using the patterned photoresist layer as an etching mask to form a contact hole.

The predetermined etching method may include etching the anti-reflection layer, etching the pre-metal dielectric layer by a predetermined depth, and etching an active region.

### DRAWINGS

FIG. 1 is a cross-sectional view illustrating a related method of manufacturing a semiconductor device.

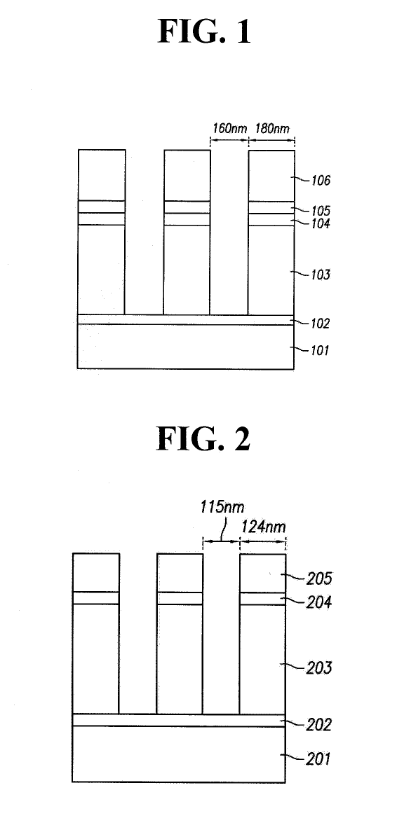

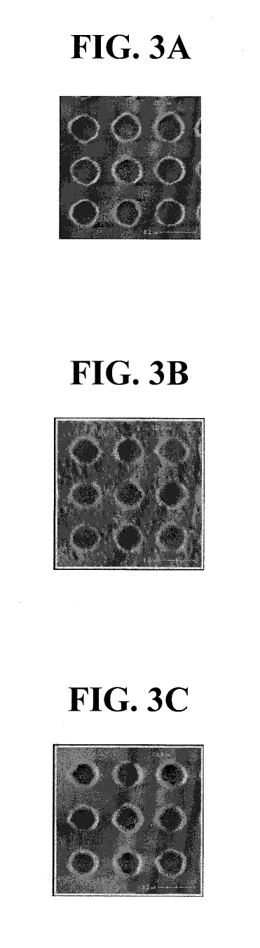

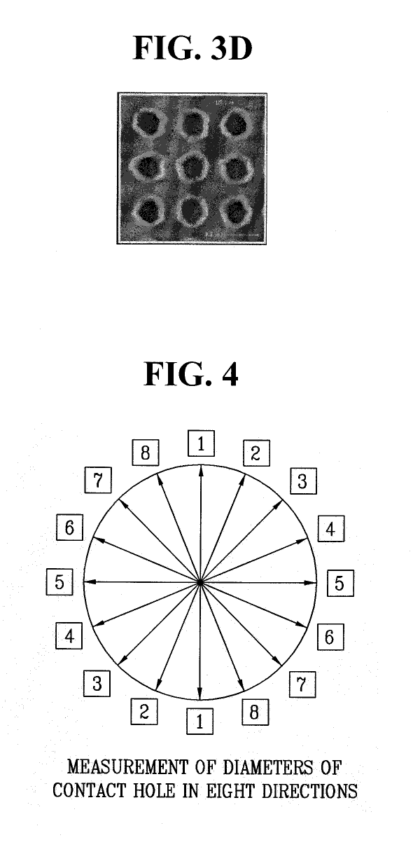

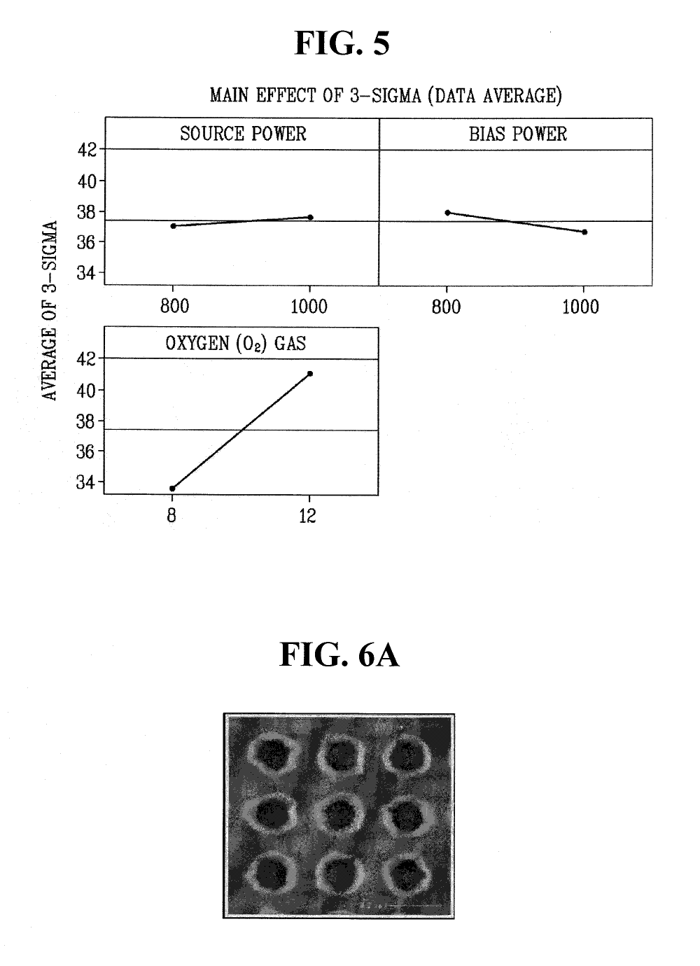

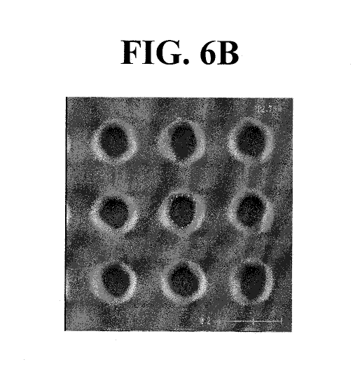

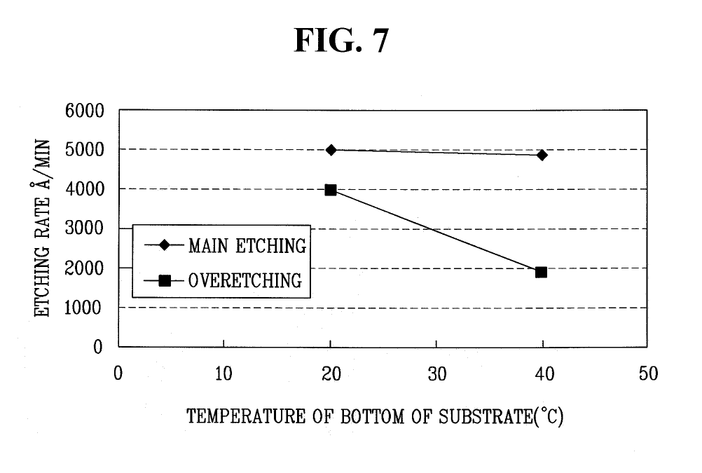

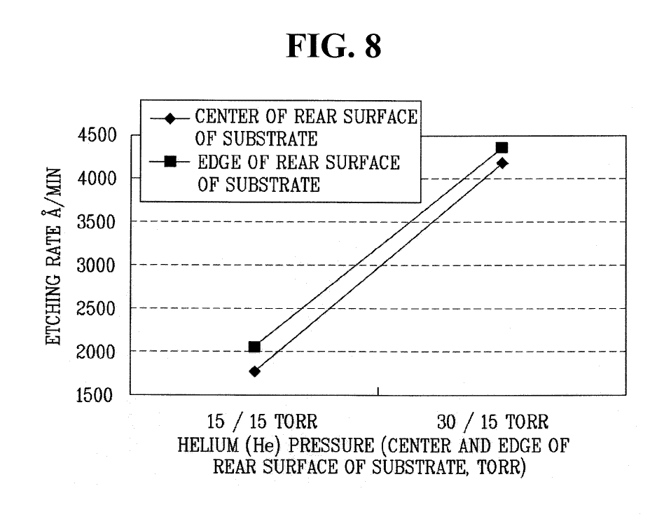

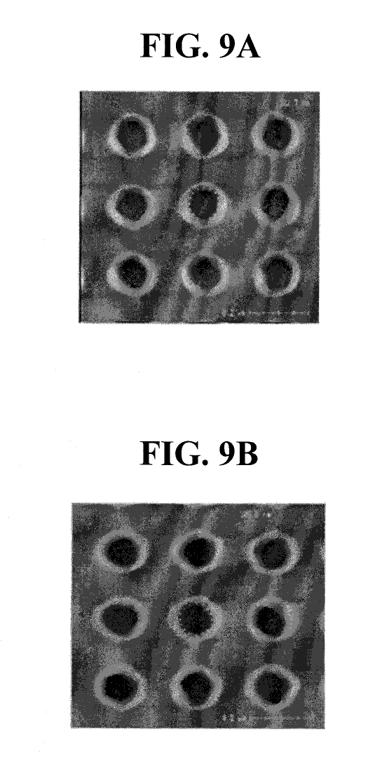

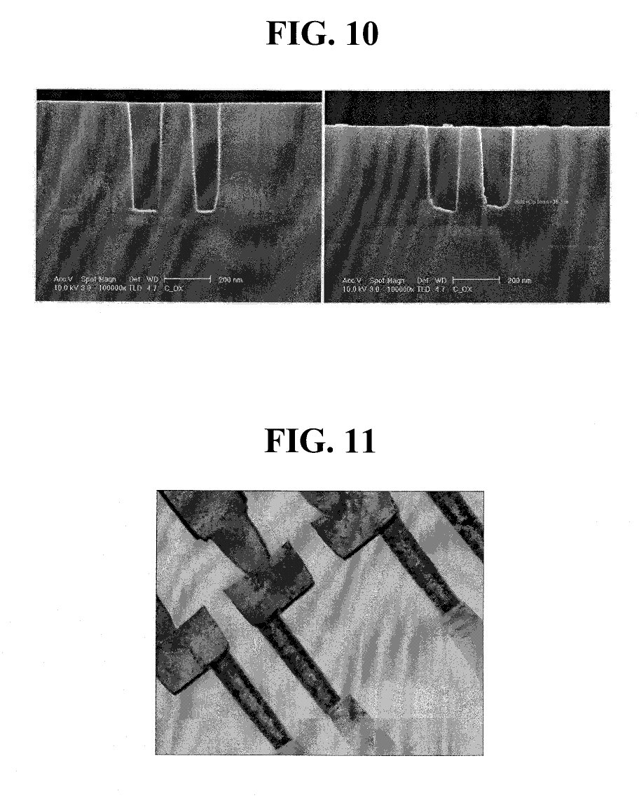

Example FIG. 2 is a cross-sectional view illustrating a method of manufacturing a semiconductor device according to embodiments.

Example FIGS. 3A to 3D are front views showing resultant materials according to embodiments.

Example FIG. 4 is a cross-sectional view illustrating factors having influence on the resultant material according to embodiments.

Example FIG. 5 is a graph showing an experimental result explaining the factors having influence on the resultant material according to embodiments.

Example FIGS. 6A to 6B are front views showing resultant materials according to embodiments.

Example FIG. 7 is a graph showing a relationship between a temperature of a bottom of a rear surface of a substrate and an etching rate in a process of manufacturing a semiconductor device according to embodiments.

Example FIG. 8 is a graph showing a relationship between a pressure of helium and an etching rate in a process of manufacturing a semiconductor device according to embodiments.

Example FIG. 9 is a front view showing a resultant material according to embodiments.

Example FIG. 10 is a cross-sectional view of the resultant material of the semiconductor device according to embodiments.

Example FIG. 11 is a cross-sectional view of the resultant material of the semiconductor device according to embodiments when observed by a transmission electron microscope.

### DESCRIPTION

An etching method for forming a contact hole for connecting a first metal line M1 of a multi-layer metal line according to embodiments will be described with reference to example FIG. 2.

As shown in example FIG. 2, a plurality of layers are formed over a semiconductor substrate 201 which may include a plurality of lower structures. The plurality of layers may include a metal barrier layer 202, a pre-metal dielectric layer 203, and an anti-reflection layer 204. The metal barrier 202 may be formed with a thickness of 320 Å to 380 Å using a metal film including metal and a silicon nitride film. The pre-metal dielectric layer 203 may formed with a thickness of 4400 Å to 5400 Å using a undoped oxide including, for example, undoped silicate glass (USG) or boro-phospho silicate glass (BPSG). The anti-reflection layer 204 may be formed with a thickness of 450 Å to 550 Å. Thereafter, a PR material for ArF may be coated over the anti-reflection layer 204 with a thickness of approximately 2100 Å to 2500 Å to form a photoresist (PR) layer 205. Subsequently, the PR layer 205 is patterned using an ArF light source in a contact hole shape.

The plurality of layers formed over the semiconductor substrate 201, that is, the anti-reflection layer 204, the pre-metal dielectric layer 203 and the metal barrier layer 202, may be etched using the patterned PR layer 205 as an etching mask, thereby forming a contact hole. The etching step for forming the contact hole may be divided into three etching steps including a first etching step, a second main etching step and a third overetching step.

After performing the photoresist process, the substrate may be moved to a reaction chamber for a reactive ion etching (RIE) process. The anti-reflection layer 204 may be etched using the patterned PR film as the etching mask. To perform this etching process, for example, Ar, CF₄, CH₂F₂, O₂ and He may be injected into the reaction chamber to etch the anti-reflection layer using these plasmas. The etching step may be performed for about 40 to 50 seconds. The flow rate of Ar gas may be, for example, set to approximately 180 sccm to 220 sccm, the flow rate of CF4 gas may be set to approximately 50 sccm to 60 sccm, the flow rate of CH₂F₂ gas may be set to approximately 7 sccm to 9 sccm, and the flow rate of O₂ gas may be set to 9 sccm to 11 sccm. The pressure of the reaction chamber may be set to approximately 100 mT to 120 mT, source power may be set to approximately 350 W to 450 W, and He gas may be supplied to the center and the edge of the rear surface of the substrate with a pressure of approximately 14 Torr to 16 Torr.

The pre-metal dielectric layer 203 may be etched to a predetermined depth. This etching step may be performed for approximately 35 seconds to 45 seconds. The flow rate of Ar gas may be set to approximately 230 sccm to 270 sccm, the flow rate of C₄F₆ gas may be set to approximately 9 sccm to 11 sccm, the flow rate of CH₂F₂ gas may be set to approximately 11 sccm to 13 sccm, and the flow rate of O₂ gas may be set to approximately 13 sccm to 15 sccm. The pressure of the reaction chamber may be set to approximately 55 mT to 65 mT. The source power may be set to approximately 720 W to 880 W, and bias power may be set to approximately 1100 W to 1300 W. He gas may be supplied to the center and the edge of the rear surface of the substrate with a pressure of approximately 14 Torr to 16 Torr.

The overetching step may be performed through a touch-up (TUP) process for etching an active region that may be contacted by the contact hole. This etching step may be performed for approximately 55 seconds to 65 seconds. The flow rate of Ar gas may be set to approximately 230 sccm to 270 sccm, the flow rate of C₄F₆ gas may be set to approximately 11 sccm to 13 sccm, the flow rate of CO gas may be set to approximately 90 sccm to 110 sccm, and the flow rate of O₂ gas may be set to approximately 8.1 sccm to 9.9 sccm. The pressure of the reaction chamber may be set to approximately 80 mT to 100 mT. Source power may be set to approximately 720 W to 880 W, and bias power may be set to approximately 720 W to 800 W. He gas may be supplied to the center and the edge of the rear surface of the substrate with respective pressures of approximately 23 Torr to 27 Torr and approximately 14 Torr to 16 Torr.

In the third overetching step, optimal values of the flow rate of O₂ gas, which is a factor for determining circularity of the contact hole, and the pressure of He gas, which is a factor relating to etch stop, may be obtained by the following exemplary experiment. This exemplary experiment may find factors causing circularity of the contact hole to deteriorate when the hard mask is not used. It may also determine why etch stop occurs due to a high temperature of a bottom of a substrate in a device having a large aspect ratio. The aim is to maximize the circularity and control the etch stop.

Accordingly, conditions used in three etching steps of the experiment are as follows.

In the first etching step, the flow rate of Ar gas may be set to approximately 180 sccm to 220 sccm, the flow rate of CF4 gas may be set to approximately 50 sccm to 60 sccm, the flow rate of CF₄F₆ gas may be set to approximately 7 sccm to 9 sccm, and the flow rate of O₂ gas may be set to approximately 9 sccm to 11 sccm. The pressure of the reaction chamber may be set to approximately 100 mT to 120 mT. Source power may be set to approximately 350 W to 450 W, and He gas is supplied to the center and the edge of the rear surface of the substrate with a pressure of approximately 14 Torr to 16 Torr.

In the second main etching step, the flow rate of Ar gas may be set to approximately 230 sccm to 270 sccm, the flow rate of C₄F₆ gas may be set to approximately 9 sccm to 11 sccm, the flow rate of CH₂F₂ gas may be set to approximately 11 sccm to 13 sccm, the flow rate of O₂ gas may be set to approximately 13 sccm to 15 sccm, the pressure of the reaction chamber may be set to approximately 55 mT to 65 mT. Source power may be set to approximately 720 W to 880 W, and bias power may be set to approximately 1100 W to 1300 W. He gas may be supplied to the center and the edge of the rear surface of the substrate with a pressure of approximately 14 Torr to 16 Torr.

In the third overetching step, the flow rate of Ar gas may be set to approximately 230 sccm to 270 sccm, the flow rate of C₄F₆ gas may be set to approximately 11 sccm to 13 sccm, the flow rate of CO gas may be set to approximately 90 sccm to 110 sccm, and the flow rate of O₂ gas may be set to approximately 11 sccm to 13 sccm. The pressure of the reaction chamber may be set to approximately 80 mT to 100 mT. Source power may be set to approximately 720 W to 880 W, and bias power may be set to approximately 720 W to 800 W. He gas may be supplied to the center and the edge of the rear surface of the substrate with a pressure of approximately 14 Torr to 16 Torr.

As a result, example FIGS. 3A to 3D are front views of the semiconductor device after the steps are performed through the above-described exemplary experiment, when observed by a scanning electron microscope (SEM). Example FIG. 3A is a front view showing a pattern of a PR layer in a contact hole shape for forming a contact hole. Example FIG. 3B is a front view showing the first etching step for etching the anti-reflection layer. Example FIG. 3C is a front view showing the second main etching step for etching the pre-metal dielectric layer including the anti-reflection layer by a predetermined depth. Example FIG. 3D is a front view showing the third overetching step for etching an active region that may be contacted by the contact hole.

As shown in example FIG. 3C, the shape of the hole is substantially similar to the shape of the contact hole of the PR layer until the second main etching step. The circularity of the hole deteriorates after the third overetching step. Accordingly, the third overetching step may have influence on the circularity of the hole. As a result, factors which degrade the circularity of the contact hole may be the flow rate of O₂ gas, the source power and the bias power of the third overetching step.

To explain the factors, as shown in example FIG. 4, the experiment was divided into two levels (3-sigma). The main factor in the experimental result is the flow rate of O₂ gas. This experiment indicates a method of measuring the circularity of the hole with 3-sigma of eight pieces of data. Example FIG. 5 shows an experimental result, in which a vertical axis indicates a 3-sigma value of the diameter of the hole measured in eight directions and a horizontal axis indicates the level of the factor. As the value of the vertical axis decreases, the circularity of the hole is maximized. Accordingly, the factor degrading the circularity of the contact hole is checked by the experiment.

In embodiments, a process of reducing the flow rate of O₂ gas in the third overetching step may be performed. Example FIGS. 6A and 6B are front views showing the shapes of the holes before and after the flow rate of the O₂ gas is changed, respectively. That is, example FIGS. 6A and 6B show the shapes of the contact holes when the flow rate of the oxygen gas is approximately 12 sccm and approximately 8 sccm, respectively. As described above, when the flow rate of O₂ gas is reduced to a range of approximately 8.1 sccm to approximately 9.9 sccm, the circularity of the hole is improved. However, as the flow rate of the O₂ gas is reduced, etch stop may occur. When the temperature of the bottom of the substrate increases, the etching rate of oxide tends to decrease.

Accordingly, as shown in example FIG. 7, when the temperature of the bottom of the substrate is approximately 40° C., the etching rate of the third overetching step decreases to less than half the etching rate when the temperature of the bottom of the substrate is approximately 20° C. This is because, if the temperature of the bottom of the substrate increases, the temperature of the wafer increases, a radical absorption rate is reduced, and thus the etching rate is reduced. Accordingly, to increase the etching rate, the flow rate of O₂ gas should increase or a voltage should increase. However, when these factors are changed, the circularity of the hole deteriorates. Accordingly, these factors cannot be changed.

To solve the etch stop issue, the flow rate of helium (He) gas supplied to the center of the rear surface of the substrate may be increased according to embodiments. Referring to example FIG. 8, a graph showing a comparison between the etching rate when He gas supplied to the center of the rear surface of the substrate at approximately 14 Torr to 16 Torr and at approximately 27 Torr to 33 Torr. He supply pressure at the edge of the rear surface of the substrate is kept at approximately 14 Torr to 16 Torr. When the flow rate of the He gas supplied to the center increases, a wafer cooling effect increases while improving the uniformity between the center and the edge of the rear surface of the substrate. The etching rate increases without deteriorating the circularity of the hole, thereby maximizing the third overetching process margin. When the pressure of the He gas supplied to the center of the rear surface of the substrate is increased, etch stop does not occur although the temperature of the bottom of the substrate increases.

The results of observing the contact holes according to embodiments using the SEM are shown in example FIGS. 9, 10 and 11. Example FIG. 9A is a front view showing a contact hole obtained by performing the etching step when the temperature of the bottom of the substrate is approximately 20° C. and example FIG. 9B is a front view showing a contact hole obtained by performing the etching step when the pressure of the He gas supplied to the center of the rear surface of the substrate increases to improve the etching stop margin. It can be seen that the shape of the hole is not changed although the pressure of the He gas is increased to increase the etching rate.

Next, example FIG. 10 shows a 90-nm logic device in which a contact hole connects to an active region and a control gate while etch stop does not occur, through a SEM profile. Example FIG. 11 shows a 90-nm logic device having a contact hole obtained by performing the third overetching step while etch stop does not occur, through a transmission electron microscope (TEM).

According to embodiments, it is possible to simplify a process and to maximize productivity of a device by performing etching steps using only a PR for ArF on a pre-metal dielectric layer and an anti-reflection layer without using a hard mask. According to embodiments, it is possible to prevent deterioration of circularity of a contact hole due to low etch resistance of the PR for ArF when the hard mask is not used. In addition, it is possible to maximize the reliability of the device by reducing the flow rate of O₂ gas.

According to embodiments, it is possible to solve a problem such as a premature etch stop which may occur due to a 90-nm device having a large aspect ratio and a high temperature of the bottom of the substrate. In addition, it is possible to improve electrical characteristics by bringing a contact of a first metal line M1 into contact with an active region or a gate region to efficiently transmit an electrical signal output from the metal line to a desired region.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method for forming a semiconductor device with a critical dimension equal to or less than approximately 90 nanometers comprising:
forming a plurality of layers over a semiconductor substrate, said substrate having a lower structure including a transistor;
forming a photoresist layer over the plurality of layers and patterning the photoresist layer to include at least one contact hole shape; and
etching the plurality of layers through a predetermined etching method using the patterned photoresist layer as an etching mask to form at least one contact hole.

2. The method of claim 1, wherein the plurality of layers include a metal barrier layer, a pre-metal dielectric layer and an anti-reflection layer.

3. The method of claim 2, wherein said etching includes:
etching the anti-reflection layer;
etching the pre-metal dielectric layer to a predetermined depth; and
overetching an active region in said transistor.

4. The method of claim 3, wherein said contact hole connects to said active region.

5. The method of claim 3, wherein etching said antireflective layer is performed for approximately 40 seconds to 50 seconds, wherein a flow rate of Ar gas is set between approximately 180 sccm and 220 sccm, a flow rate of CF₄ gas is set between approximately 50 sccm and 60 sccm, a flow rate of CH₂F₂ gas is set between approximately 7 sccm and 9 sccm, a flow rate of O₂ gas is set between approximately 9 sccm and 11 sccm, a pressure of a reaction chamber is set between approximately 100 mT and 120 mT, and source power is set between approximately 350 W and 450 W.

6. The method of claim 3, wherein said etching the pre-metal dielectric layer is performed for approximately 35 seconds to 45 seconds, a flow rate of Ar gas is set between approximately 230 sccm and 270 sccm, a flow rate of C₄F₆ gas is set between approximately 9 sccm and 11 sccm, a flow rate of CH₂F₂ gas is set between approximately 11 sccm and 13 sccm, a flow rate of O₂ gas is set between approximately 13 sccm and 15 sccm, a pressure of a reaction chamber is set between approximately 55 mT and 65 mT, source power is set between approximately 720 W and 880 W, and bias power is set between approximately 1100 W and 1300 W.

7. The method of claim 3, wherein said overetching an active region is performed for between approximately 55 seconds to 65 seconds, a flow rate of Ar gas is set between approximately 230 sccm and 270 sccm, a flow rate of C₄F₆ gas is set between approximately 11 sccm and 13 sccm, a flow rate of CO gas is set between approximately 90 sccm and 110 sccm, a flow rate of O₂ gas is set between approximately 8.1 sccm and 9.9 sccm, a pressure of a reaction chamber is set between approximately 80 mT and 100 mT, source power is set between approximately 720 W and 880 W, bias power is set between approximately 720 W and 800 W and He gas is supplied to a center and an edge of a rear surface of the substrate with respective pressures of between approximately 23 Torr to 27 Torr and between approximately 14 Torr to 16 Torr.

8. The method of claim 3, wherein said etching the anti-reflection layer, said etching the pre-metal dielectric layer, and said overetching an active region use a reactive ion etching method and are performed in-situ in the same etching chamber.

9. The method of claim 3, wherein a temperature of a bottom of the substrate is held at approximately 20° C.

10. The method of claim 1, wherein an ArF light source is used to pattern the photoresist.

11. An apparatus configured to form a semiconductor device with a critical dimension equal to or less than approximately 90 nanometers, said apparatus configured to:
form a plurality of layers over a semiconductor substrate, said substrate having a lower structure including a transistor;
form a photoresist layer over the plurality of layers and patterning the photoresist layer to include at least one contact hole shape; and
etch the plurality of layers through a predetermined etching method using the patterned photoresist layer as an etching mask to form at least one contact hole.

12. The apparatus of claim 11, wherein the plurality of layers include a metal barrier layer, a pre-metal dielectric layer and an anti-reflection layer.

13. The apparatus of claim 12, wherein said etch configuration includes an apparatus configured to:
etch the anti-reflection layer;
etch the pre-metal dielectric layer to a predetermined depth; and
overetch an active region in said transistor.

14. The apparatus of claim 13, wherein said contact hole connects to said active region.

15. The apparatus of claim 13, wherein a configuration to etch said antireflective layer is configured to perform for approximately 40 seconds to 50 seconds, wherein a flow rate of Ar gas is set between approximately 180 sccm and 220 sccm, a flow rate of CF₄ gas is set between approximately 50 sccm and 60 sccm, a flow rate of CH₂F₂ gas is set between approximately 7 sccm and 9 sccm, a flow rate of O₂ gas is set between approximately 9 sccm and 11 sccm, a pressure of a reaction chamber is set between approximately 100 mT and 120 mT, and source power is set between approximately 350 W and 450 W.

16. The apparatus of claim 13, wherein a configuration to etch the pre-metal dielectric layer is configured to perform for approximately 35 seconds to 45 seconds, a flow rate of Ar gas is set between approximately 230 sccm and 270 sccm, a flow rate of C₄F₆ gas is set between approximately 9 sccm and 11 sccm, a flow rate of CH₂F₂ gas is set between approximately 11 sccm and 13 sccm, a flow rate of O₂ gas is set between approximately 13 sccm and 15 sccm, a pressure of a reaction chamber is set between approximately 55 mT and 65 mT, source power is set between approximately 720 W and 880 W, and bias power is set between approximately 1100 W and 1300 W.

17. The apparatus of claim 13, wherein a configuration to overetch said active region is configured to perform for between approximately 55 seconds to 65 seconds, a flow rate of Ar gas is set between approximately 230 sccm and 270 sccm, a flow rate of C₄F₆ gas is set between approximately 11 sccm and 13 sccm, a flow rate of CO gas is set between approximately 90 sccm and 110 sccm, a flow rate of O₂ gas is set between approximately 8.1 sccm and 9.9 sccm, a pressure of a reaction chamber is set between approximately 80 mT and 100 mT, source power is set between approximately 720 W and 880 W, bias power is set between approximately 720 W and 800 W and He gas is supplied to a center and an edge of a rear surface of the substrate with respective pressures of between approximately 23 Torr to 27 Torr and between approximately 14 Torr to 16 Torr.

18. The apparatus of claim 13, wherein a configuration to etch the anti-reflection layer, etch the pre-metal dielectric layer, and overetch an active region is configured to use a reactive ion etching method and is configured to perform in-situ in the same etching chamber.

19. The apparatus of claim 13, wherein the apparatus is configured to hold a temperature of a bottom of the substrate at approximately 20° C.

20. The apparatus of claim 11, wherein the apparatus is configured to use an ArF light source to pattern the photoresist.
